(19) United States
(12) Patent Application Publication
(10) Pub. No.: US 2016/0047041 A1
(43) Pub. Date: Feb. 18, 2016

(54) NOZZLE FOR DEPOSITION SOURCE AND THIN FILM DEPOSITING APPARATUS INCLUDING THE NOZZLE

(71) Applicant: Samsung Display Co., Ltd., Yongin-city (KR)

(72) Inventors: Kookchol PARK, Yongin-City (KR); Sokwon NOH, Yongin-City (KR)

(21) Appl. No.: 14/665,393

(22) Filed: Mar. 23, 2015

(30) Foreign Application Priority Data
Aug. 18, 2014 (KR) 10-2014-0106956

(51) Int. Cl. C23C 16/455

(52) U.S. Cl. CPC C23C 16/45563

(57) ABSTRACT

A deposition source nozzle including a convergence guide configured to guide a deposition source material discharged from the deposition source nozzle to a convergence direction with respect to the deposition source nozzle, and a divergence guide configured to guide the deposition source material discharged from the deposition source nozzle to a divergence direction with respect to the deposition source nozzle, the divergence direction being opposite to the convergence direction with respect to the discharging direction of the deposition source material.

### CROSS-REFERENCE TO RELATED APPLICATION

This application claims priority from and the benefit of Korean Patent Application No. 10-2014-0106956, filed on Aug. 18, 2014, which is hereby incorporated by reference for all purposes as if fully set forth herein.

### BACKGROUND

1. Field

Exemplary embodiments of the present invention relate to a thin film depositing apparatus configured to form a thin film on a surface of an object by generating a deposition source material vapor, and a deposition source nozzle used in the thin film depositing apparatus.

2. Discussion of the Background

In forming a thin film, such as a thin film of an organic light emitting display, a deposition process of generating a deposition source material vapor, and discharging the vapor toward a substrate, to apply the deposition source material to a surface of the substrate may be used. More particularly, a mask may be placed on a substrate and a deposition source material vapor passes through an opening of the mask to form a thin film having a desired pattern, on the substrate.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments of the present invention provide a deposition source nozzle and a thin film depositing apparatus including the deposition source nozzle.

Additional aspects will be set forth in the detailed description which follows and, in part, will be apparent from the disclosure, or may be learned by practice of the inventive concept.

An exemplary embodiment of the present invention provides a deposition source nozzle including a convergence guide configured to guide a deposition source material discharged from the deposition source nozzle in a convergence direction with respect to the deposition source nozzle, and a divergence guide configured to guide the deposition source material discharged from the deposition source nozzle in a divergence direction with respect to the deposition source nozzle, the divergence direction being opposite to the convergence direction with respect to the discharging direction of the deposition source material.

The discharged deposition source material may be configured to be guided first by the convergence guide, and then by the divergence guide.

The divergence guide may surround the convergence guide.

The convergence guide may be inclined towards the convergence direction at about 10 to about 20 degrees with respect to a discharging direction of the deposition source material.

The divergence guide may be inclined towards the divergence direction at about 30 to about 40 degrees with respect to a discharging direction of the deposition source material.

The deposition source nozzle may further include a nozzle body connected to a deposition source storage unit in including the deposition source material disposed therein, and the convergence guide and the divergence guide may be disposed at an outlet of the nozzle body.

A length of the divergence guide may be greater than that of the convergence guide.

An exemplary embodiment of the present invention also provides a thin-film depositing apparatus including a deposition source storage unit that includes a deposition source material disposed therein, and a deposition source nozzle including a convergence guide configured to guide the discharged deposition source material in a convergence direction with respect to the deposition source nozzle, and a divergence guide configured to guide the discharged deposition source material in a divergence direction with respect to the deposition source nozzle, the divergence direction being opposite to the convergence direction with respect to the discharging direction of the deposition source material, in which the deposition source nozzle is connected to the deposition source storage unit and configured to discharge the deposition source material towards a deposition object.

The discharged deposition source material may be configured to be guided first by the convergence guide, and then by the divergence guide.

The divergence guide may surround the convergence guide.

The convergence guide may be inclined towards the convergence direction at about 10 to about 20 degrees with respect to a discharging direction of the deposition source material.

The divergence guide may be inclined towards the divergence direction at about 30 to about 40 degrees with respect to a discharging direction of the deposition source material.

The thin-film depositing apparatus may further include a nozzle body connected to the deposition source storage unit, in which the convergence guide and the divergence guide are disposed at an outlet of the nozzle body.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the present invention, and, together with the description, serve to explain principles of the inventive concept.

FIG. 1 is a schematic view of a structure of a thin film depositing apparatus including a deposition source nozzle according to an exemplary embodiment of the present invention.

FIG. 2 is an extended view of the deposition source nozzle of the thin film depositing apparatus illustrated in FIG. 1.

FIG. 3 is a graph illustrating a thickness distribution ratio of a deposition layer between a deposition performed according to the exemplary embodiment of the present invention and a comparative embodiment.

FIG. 4 is a cross-sectional view of an organic light emitting display manufactured according to an exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

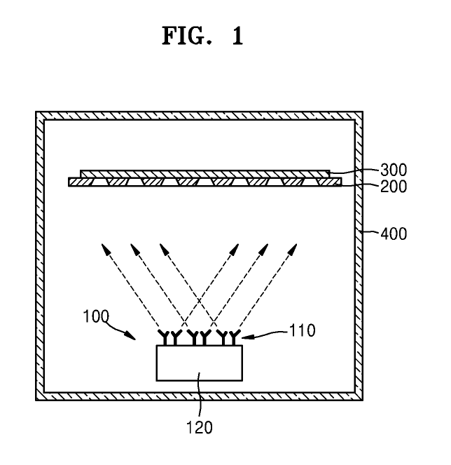

FIG. 1 is a schematic view of a structure of a thin film depositing apparatus including a deposition source nozzle, according to an exemplary embodiment of the present invention.

Referring to FIG. 1, the thin film depositing apparatus according to the present exemplary embodiment may include a chamber 400 including a mask 200 used to form a desired pattern on a substrate 300, and a deposition source unit 100 that discharges a deposition gas toward the substrate 300.

The deposition source unit 100 discharges a deposition gas in the chamber 400, the deposition gas may pass through an opening formed in the mask 200 to be deposited on the substrate 300, thereby forming a thin film having a predetermined pattern.

The deposition source unit 100 includes a deposition source storage unit 120 accommodating a deposition source material that is to be discharged toward the substrate 300. A deposition source nozzle 110 is connected to the deposition source storage unit 120. Accordingly, the deposition source material accommodated in the deposition source storage unit 120 is discharged through the deposition source nozzle 110 toward the substrate 300.

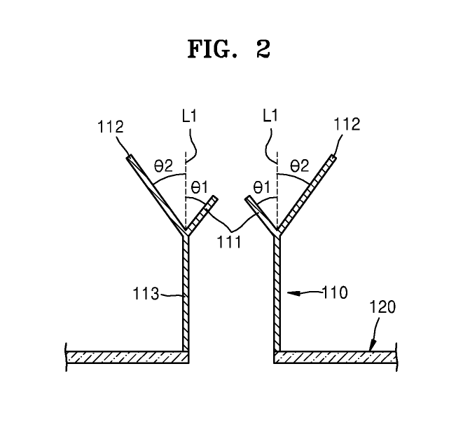

FIG. 2 is an extended view of the deposition source nozzle 110 illustrated in FIG. 1. Referring to FIG. 2, the deposition source nozzle 110 includes a nozzle body 113 that is connected to the deposition source storage unit 120, and a convergence guide 111 and a divergence guide 112 that guide a discharging direction of a deposition source material are respectively formed at an outlet of the nozzle body 113.

The convergence guide 111 may be inclined in a direction that gradually reduces a width of the deposition source nozzle 110. More particularly, the convergence guide 111 may be inclined in a direction in which the deposition source material converges (i.e., a convergence direction) with respect to a line L1 extending in a discharging direction of the deposition source material. The convergence direction may be at an angle θ₁ of about 10 to about 20 degrees. When the deposition source material is discharged from the nozzle body 113, the convergence guide 111 may centralize the discharge direction of the deposition source material. Accordingly, the discharging direction of the deposition source material may be more linear and straight, which may improve a radiation coefficient. The radiation coefficient is a degree of straightness of a discharged deposition source material. The higher the radiation coefficient, the less the deposition source material may spread, and the straighter the direction in which the deposition source material is discharged.

The divergence guide 112 may be formed to surround the convergence guide 111. The divergence guide 112 may be inclined in a direction that gradually increases the width of the deposition source nozzle 110. More particularly, the divergence guide 112 may be inclined in a direction opposite to the convergence direction. A divergence direction may be at an angle θ₂ of about 30 to 40 degrees with respect to the discharging direction L1. The divergence guide 112 may guide the discharged deposition source material after it is guided by the convergence guide 111. As the convergence guide 111 may limit the deposition source material from spreading sideways when discharged from the deposition source nozzle 110, and guide the deposition source material to be deposited on the substrate 300 over an appropriate range, the divergence guide 112 may regulate the extent in which the deposition source material spreads. That is, due to the convergence guide 111, the deposition source material may converge toward a center of the opening of the nozzle body 113 and the straightness of the discharging direction of the deposition source material toward the substrate 300 increases. The divergence guide 112 may control the extent in which the deposition source material diverges and spreads so as to improve a radiation coefficient based on the combination of the convergence guide 111 and the divergence guide 112.

In an exemplary embodiment of the present invention, the divergence guide 112 may be formed at the end of the convergence guide 111 (not shown). More particularly, the convergence guide 111 may be formed at an outlet of the nozzle body 113 and inclined in a direction in which the deposition source material converges with respect to a line L1 extending in a discharging direction of the deposition source material. The convergence direction may be at an angle θ₁ of about 10 to about 20 degrees. The divergence guide 112 may formed at the opposite end of the convergence guide 111 from the nozzle body 113, and inclined in a direction opposite to the convergence direction. A divergence direction may be at an angle θ₂ of about 30 to 40 degrees with respect to the discharging direction L1.

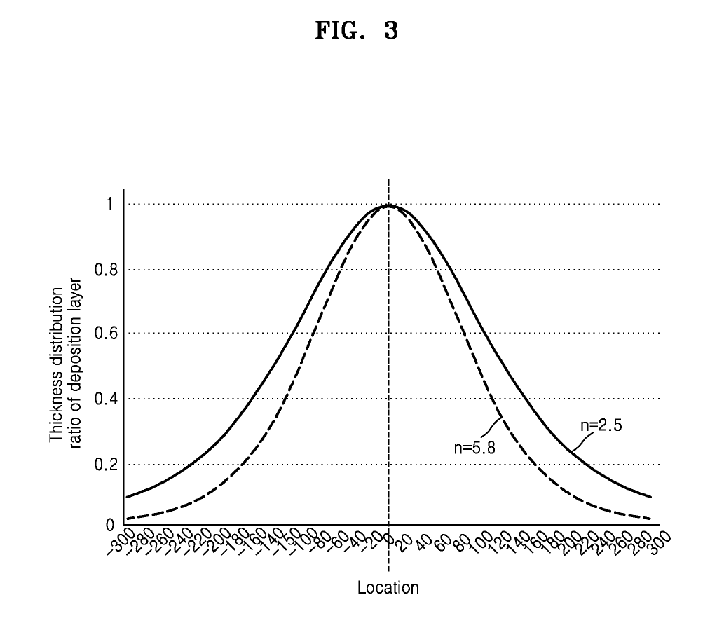

FIG. 3 is a graph illustrating a thickness distribution ratio of a deposition layer from the deposition process according to the present exemplary embodiment and a comparative embodiment. Referring to FIG. 3, the thickness distribution of a deposition layer converges to the center of the opening of the nozzle body 113 according to the present exemplary embodiment that includes the deposition source nozzle 110 including the convergence guide 111 and the divergence guide 112 (radiation coefficient n=5.8), as compared to the comparative embodiment (radiation coefficient n=2.5). As shown in FIG. 3, if the deposition source material is discharged while being guided by the convergence guide 111 and the divergence guide 112 according to the present exemplary embodiment, the straightness of the discharging direction of the deposition source material may be improved and the deposition source material may pass through the opening of the mask 200 in a direction that is substantially perpendicular to the mask 200. Thus, a thickness distribution of the deposition layer may converge to the center of the opening of the nozzle body 113 without spreading sideways. As the deposition layer may be formed on the substrate 300 while accurately corresponding to the opening of the mask 200, shadows that correspond to deposition layers formed at incorrect positions due to the deposition source material passing through the mask 200 at an oblique angle may be reduced.

The thin film depositing apparatus including the deposition source nozzle 110 according to the present exemplary embodiment may be implemented as described below.

First, the substrate 300 and the mask 200 may be placed in the chamber 400 in which the deposition source unit 100 is prepared as illustrated in FIG. 1. The deposition source unit 100 includes the deposition source nozzle 110 according to the present exemplary embodiment described above.

When a deposition source material is discharged from the deposition source unit 100, the deposition source material may be deposited on the substrate 300 through the opening (not shown) of the mask 200 to form a thin film having a desired pattern. The convergence guide 111 and the divergence guide 112 may guide the deposition source material to pass through the opening of the mask 200 substantially perpendicular to the mask 200. Accordingly, deposition defects such as shadows may be reduced.

The thin film depositing apparatus according to the present exemplary embodiment may be used, for example, in forming a pattern of an organic layer or of an opposite electrode of an organic light emitting display device.

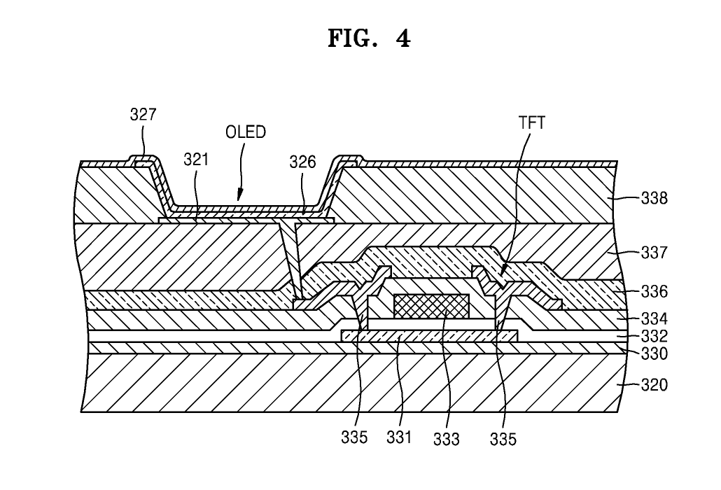

FIG. 4 is a cross-sectional view of an organic light emitting display manufactured according to the present exemplary embodiment.

Referring to FIG. 4, a buffer layer 330 is formed on a substrate 320, and a thin film transistor (TFT) is disposed on the buffer layer 330.

The TFT includes a semiconductor active layer 331, a gate insulation layer 332 formed to cover the active layer 331, and a gate electrode 333 formed on the gate insulation layer 332.

An interlayer insulation layer 334 is formed to cover the gate electrode 333, and source and drain electrodes 335 are formed on the interlayer insulation layer 334.

The source and drain electrodes 335 respectively contact a source area and a drain electrode of the active layer 331 through contact holes formed in the gate insulation layer 332 and the interlayer insulation layer 334.

A pixel electrode 321 of an organic light emitting diode OLED is connected to the source and drain electrodes 335. The pixel electrode 321 is formed on a planarization layer 337, and a pixel defining layer 338 is formed to cover the pixel electrode 321. After forming an opening in the pixel defining layer 338, an organic layer 326 of the organic light emitting diode OLED is formed, and an opposite electrode 327 is deposited on the organic layer 326.

According to the present exemplary embodiment, by preparing the opening of the mask 200 corresponding to the organic layer 326 of the organic light emitting diode OLED, the organic layer 326 having a precise pattern with reduced shadow defects may be formed.

A precise pattern of the opposite electrode 327 may be formed by using the opening of the mask 200 that corresponds to the pattern.

Accordingly, by using the deposition source nozzle and the thin film depositing apparatus according to the exemplary embodiments of the present invention, straightness of the deposition source material discharged through the deposition source nozzle may be improved, thereby effectively reducing deposition defects like shadows.

Although certain exemplary embodiments and implementations have been described herein, other embodiments and modifications will be apparent from this description. Accordingly, the inventive concept is not limited to such exemplary embodiments, but rather to the broader scope of the presented claims and various obvious modifications and equivalent arrangements.

What is claimed is:

1. A deposition source nozzle, comprising:
a convergence guide configured to guide a deposition source material discharged from the deposition source nozzle in a convergence direction with respect to the deposition source nozzle; and
a divergence guide configured to guide the deposition source material discharged from the deposition source nozzle in a divergence direction with respect to the deposition source nozzle, the divergence direction being opposite to the convergence direction with respect to the discharging direction of the deposition source material.

2. The deposition source nozzle of claim 1, wherein the discharged deposition source material is configured to be guided first by the convergence guide, and then by the divergence guide.

3. The deposition source nozzle of claim 2, wherein the divergence guide surrounds the convergence guide.

4. The deposition source nozzle of claim 1, wherein the convergence guide is inclined towards the convergence direction at about 10 to about 20 degrees with respect to a discharging direction of the deposition source material.

5. The deposition source nozzle of claim 1, wherein the divergence guide is inclined towards the divergence direction at about 30 to about 40 degrees with respect to a discharging direction of the deposition source material.

6. The deposition source nozzle of claim 1, further comprising a nozzle body connected to a deposition source storage unit comprising the deposition source material disposed therein,
wherein the convergence guide and the divergence guide are disposed at an outlet of the nozzle body.

7. A thin-film depositing apparatus, comprising:
a deposition source storage unit comprising a deposition source material disposed therein; and
a deposition source nozzle, comprising:
a convergence guide configured to guide the discharged deposition source material in a convergence direction with respect to the deposition source nozzle; and
a divergence guide configured to guide the discharged deposition source material in a divergence direction with respect to the deposition source nozzle, the divergence direction being opposite to the convergence direction with respect to the discharging direction of the deposition source material,
wherein:
the deposition source nozzle is connected to the deposition source storage unit; and
the deposition source nozzle is configured to discharge the deposition source material towards a deposition object.

8. The thin-film depositing apparatus of claim 7, wherein the discharged deposition source material is configured to be guided first by the convergence guide, and then by the divergence guide.

9. The thin-film depositing apparatus of claim 8, wherein the divergence guide surrounds the convergence guide.

10. The thin-film depositing apparatus of claim 7, wherein the convergence guide is inclined towards the convergence direction at about 10 to about 20 degrees with respect to a discharging direction of the deposition source material.

11. The thin-film depositing apparatus of claim 7, wherein the divergence guide is inclined towards the divergence direction at about 30 to about 40 degrees with respect to a discharging direction of the deposition source material.

12. The thin-film depositing apparatus of claim 7, further comprising a nozzle body connected to the deposition source storage unit,
wherein the convergence guide and the divergence guide are disposed at an outlet of the nozzle body.

13. The deposition source nozzle of claim 3, wherein a length of the divergence guide is greater than a length of the convergence guide.

14. The thin-film depositing apparatus of claim 9, wherein a length of the divergence guide is greater than a length of the convergence guide.
